(19) United States
(12) Patent Application Publication
(10) Pub. No.: US 2011/0169378 A1
(43) Pub. Date: Jul. 14, 2011

(54) ACTUATOR APPARATUS AND METHODS OF MANUFACTURING ACTUATOR APPARATUS, LIQUID EJECTING HEAD, AND LIQUID EJECTING APPARATUS

(75) Inventor: Eiji OSAWA, Chino-shi (JP)

(73) Assignee: SEIKO EPSON CORPORATION, Tokyo (JP)

(21) Appl. No.: 12/983,480

(22) Filed: Jan. 3, 2011

(30) Foreign Application Priority Data
Jan. 9, 2010 (JP) 2010-003447

(51) Int. Cl. H01L 41/16; H01L 41/22

(52) U.S. Cl. 310/363; 29/25.35

(57) ABSTRACT

Oxygen defect of PZT can be suppressed from being generated because a temperature of a piezoelectric layer containing the PZT when a first layer of an upper electrode is formed is equal to or lower than 250° C. If the first layer containing Ir is formed on the piezoelectric layer in a state where the piezoelectric layer as a substrate is at the temperature of equal to or lower than 250° C., a compression stress is generated on the first layer. Then, a second layer having a tensile stress is formed on the first layer on which the compression stress is generated. This makes it possible to eliminate deflection on an entire piezoelectric element. Accordingly, since an initial deflection is small, reduction in the deflection amount of the piezoelectric element can be suppressed. Therefore, an actuator apparatus in which reduction in a displacement amount can be suppressed can be obtained.

This application claims a priority to Japanese Patent Application No. 2010-003447 filed on Jan. 9, 2010 which is hereby expressly incorporated by reference herein in its entirety.

### BACKGROUND

1. Technical Field

The present invention relates to an actuator apparatus utilizing displacement of a piezoelectric layer, a method of manufacturing the actuator apparatus, a method of manufacturing a liquid ejecting head using the actuator apparatus, and a method of manufacturing a liquid ejecting apparatus using the actuator apparatus.

2. Related Art

An actuator apparatus utilizing displacement of a piezoelectric layer has been known. For example, there is an actuator apparatus which deforms a vibration plate by displacement of a piezoelectric layer.

Further, a liquid ejecting head which includes an actuator apparatus and ejects liquid in a pressure generation chamber and a liquid ejecting apparatus which includes the liquid ejecting head have been known. The actuator apparatus is configured such that a part of the pressure generation chamber is formed with an elastic film and a piezoelectric element is formed on a surface of the elastic film so as to deform a vibration plate including the elastic film by displacement of a piezoelectric layer.

The piezoelectric layer has a crystal structure represented by lead zirconate titanate (PZT) or the like. The piezoelectric element is formed by sandwiching the piezoelectric layer between a lower electrode and an upper electrode. The piezoelectric element is driven and deformed by applying a voltage across the lower electrode and the upper electrode.

An actuator apparatus, an ink jet recording head as a liquid ejecting head, and an ink jet recording apparatus as a liquid ejecting apparatus have been known (for example, see Japanese Patent NO. 4202467). In the actuator apparatus, the ink jet recording head and the ink jet recording apparatus, a piezoelectric vibrator as a piezoelectric element is deflected in a convex form such that a volume of a pressure generation chamber is increased, and then, deformed in a concave form so as to increase a displacement amount thereof.

FIG. 13 is a conceptual view illustrating motions of an actuator apparatus 320. In FIG. 13, motions of the actuator apparatus 320 when voltages of 0 V, −2 V, and 23 V are applied are illustrated.

In FIG. 13, the actuator apparatus 320 is deflected in a convex form in a direction that a volume of a pressure generation chamber 12 is increased in an initial state where the applied voltage is 0 V. For example, a bias voltage of −2 V is applied to further deflect the actuator apparatus 320 in a convex form in order to fill the pressure generation chamber 12 with liquid. Thereafter, a voltage of 23 V is applied to deflect the actuator apparatus 320 in a concave form such that a volume of the pressure generation chamber 12 is reduced. With the operation, liquid in the pressure generation chamber 12 is ejected.

The actuator apparatus 320 is repeatedly displaced by applying pulses. Therefore, a deflection amount of a vibration plate which has been deformed in a convex form is reduced so as to reduce a displacement amount thereof. For example, a deflection amount d1 of the vibration plate at an initial state is reduced from 94 nm to 40 nm after the actuator apparatus 320 is displaced for nineteen billion pulses. Further, a deflection amount d2 of the vibration plate at the time of the application of the bias voltage is also reduced from an initial value of 96 nm to 57 nm after the pulse application. On the other hand, the vibration plate is deflected in a concave form when liquid is ejected. A maximum deflection amount d3 of the vibration plate at the liquid ejection is reduced from an initial value of 205 nm to 203 nm after the pulse application. That is, the deflection amount d3 is mostly unchanged after the pulse application. Accordingly, a displacement amount tends to be gradually decreased as pulses are applied. Note that the displacement amount is obtained by summing an absolute value of the deflection at the time of the bias application and that of the deflection at the time of the liquid ejection.

An aspect of the present application is to reduce change in the displacement amount by the pulse application. Meanwhile, since the deflection of the vibration plate is changed from a convex form to a concave form every time a pulse is applied, an excessive stress is applied to the piezoelectric element. This causes cracks on the piezoelectric element in some case. Further, film detachment is caused between a lower electrode and an upper electrode in some case.

### SUMMARY

An advantage of some aspects of the invention is achieved by solving at least one of the issues mentioned above and realized as the following modes or application examples.

### Application Example 1

According to an aspect of the invention, there is provided a method of manufacturing an actuator apparatus which includes a piezoelectric element formed by sandwiching a piezoelectric layer containing PZT between a lower electrode and an upper electrode containing Ir. The method of manufacturing the actuator apparatus includes a first layer formation process of forming a first layer of the upper electrode on the piezoelectric layer in a state where the piezoelectric layer is at a temperature of equal to or lower than 250° C., and a second layer formation process of forming a second layer having a tensile stress on the first layer.

According to the Application Example, a temperature of the piezoelectric layer containing PZT when the first layer of the upper electrode is formed is equal to or lower than 250° C. Therefore, oxygen defect of the PZT can be suppressed from being generated. Further, if the first layer containing Ir is formed on the piezoelectric layer in a state where the piezoelectric layer as a substrate is at the temperature of equal to or lower than 250° C., a compression stress is generated on the first layer. Then, the second layer having a tensile stress is formed on the first layer on which the compression stress is generated. This makes it possible to eliminate deflection on the entire piezoelectric element. Accordingly, since an initial deflection is small, reduction in the deflection amount of the piezoelectric element which has been deflected in a convex form can be suppressed. Note that the deflection occurs because the piezoelectric element has been repeatedly displaced. Therefore, a method of manufacturing an actuator apparatus in which reduction in a displacement amount can be suppressed can be obtained.

Further, the deflection is not changed from the convex form to the concave form. An excessive stress is not applied to the piezoelectric element. Accordingly, a method of manufacturing the actuator apparatus in which cracks can be suppressed from being generated and film detachment between the lower electrode and the upper electrode can be suppressed can be obtained.

It is noted that a state where deflection is eliminated indicates a state where the piezoelectric element is flat at an initial state and the deflection includes deflection caused by variation generated in the manufacturing processes.

### Application Example 2

In the method of manufacturing the actuator apparatus, it is preferable that a temperature at which the second layer is formed be equal to or higher than 350° C.

In the Application Example, if the temperature at which the second layer containing Ir is formed is equal to or higher than 350° C., the second layer having a tensile stress can be obtained. By forming the second layer, deflection of the first layer on which the compression stress is generated can be reduced. Accordingly, a method of manufacturing the actuator apparatus having the above-described effect can be obtained.

### Application Example 3

In the method of manufacturing the actuator apparatus, it is preferable that a thickness of the first layer be 10 nm and a thickness of the second layer be 40 nm. In the Application Example, since the thickness of the second layer is larger than that of the first layer, the tensile stress of the second layer is dominant. Further, if the thickness of the first layer is set to 10 nm and that of the second layer is set to 40 nm in the upper electrode containing Ir, the deflection on the entire piezoelectric element can be eliminated. Accordingly, a method of manufacturing the actuator apparatus having the above-described effect can be obtained.

### Application Example 4

A method of manufacturing a liquid ejecting head according to another aspect of the invention includes the manufacturing processes in the above method of manufacturing the actuator apparatus.

According to the Application Example, a method of manufacturing a liquid ejecting head having the above-described effect can be obtained.

### Application Example 5

A method of manufacturing a liquid ejecting apparatus according to still another aspect of the invention includes the manufacturing processes in the above method of manufacturing the liquid ejecting head.

According to the Application Example, a method of manufacturing a liquid ejecting apparatus having the above-described effect can be obtained.

### Application Example 6

An actuator apparatus according to still another aspect of the invention includes a piezoelectric element formed by sandwiching a piezoelectric layer containing PZT between a lower electrode and an upper electrode containing Ir. In the actuator apparatus, the upper electrode includes a first layer and a second layer, and the piezoelectric element is not deflected.

According to the Application Example, since an initial deflection is small, reduction in the deflection amount of the piezoelectric element which has been deflected in a convex form can be suppressed. Note that the deflection occurs because the piezoelectric element has been repeatedly displaced. Therefore, an actuator apparatus in which reduction in the displacement amount can be suppressed can be obtained.

### Application Example 7

In the actuator apparatus, it is preferable that a thickness of the first layer be 10 nm and a thickness of the second layer be 40 nm.

In the Application Example, when the thickness of the first layer is 10 nm and that of the second layer is 40 nm, an actuator apparatus having the above-described effect can be obtained.

### BRIEF DESCRIPTION OF THE DRAWINGS

The invention will be described with reference to the accompanying drawings, wherein like numbers reference like elements.

FIG. 1 is a schematic view illustrating an example of an ink jet recording apparatus according to an embodiment.

FIG. 2 is an exploded perspective view illustrating a schematic configuration of an ink jet recording head.

FIG. 3A is a fragmentary plan view illustrating the ink jet recording head and FIG. 3B is a schematic cross-sectional view cut along a line IIIB-IIIB in FIG. 3A.

FIG. 4 is a schematic fragmentary cross-sectional view illustrating the ink jet recording head cut along a line IV-IV in FIG. 3A.

FIG. 5 is a flowchart illustrating a method of manufacturing an actuator apparatus.

FIGS. 6A through 6C are schematic fragmentary cross-sectional views illustrating the method of manufacturing the actuator apparatus.

FIG. 7 is a graph expressing changes in conditions of piezoelectric characteristics by differences in a substrate temperature (formation temperature) as a hysteresis characteristic.

FIG. 8 is a graph illustrating a relationship between a substrate temperature and a film stress when a piezoelectric layer is set as the substrate of a first layer.

FIG. 9 is a graph illustrating a relationship between a stress of an upper electrode and a deflection amount.

FIG. 10 is a graph illustrating a hysteresis characteristic in a case where Ir of 50 nm is formed at 250° C. as the upper electrode and a hysteresis characteristic in a case where the first layer of 10 nm is formed at 250° C. and a second layer of 40 nm is formed at 350° C. as the upper electrode.

FIG. 11 is a graph illustrating a deflection reduction transition in the case where Ir of 50 nm is formed at 250° C. as the upper electrode and a deflection reduction transition in the case where the first layer of 10 nm is formed at 250° C. and the second layer of 40 nm is formed at 350° C. as the upper electrode.

FIG. 12 is a graph illustrating a displacement reduction rate in the case where Ir of 50 nm is formed at 250° C. as the upper electrode and a displacement reduction rate in the case where the first layer of 10 nm is formed at 250° C. and the second layer of 40 nm is formed at 350° C. as the upper electrode.

FIG. 13 is a conceptual view illustrating motions of an actuator apparatus.

### DESCRIPTION OF EXEMPLARY EMBODIMENTS

Hereinafter, an embodiment is described in detail with reference to drawings.

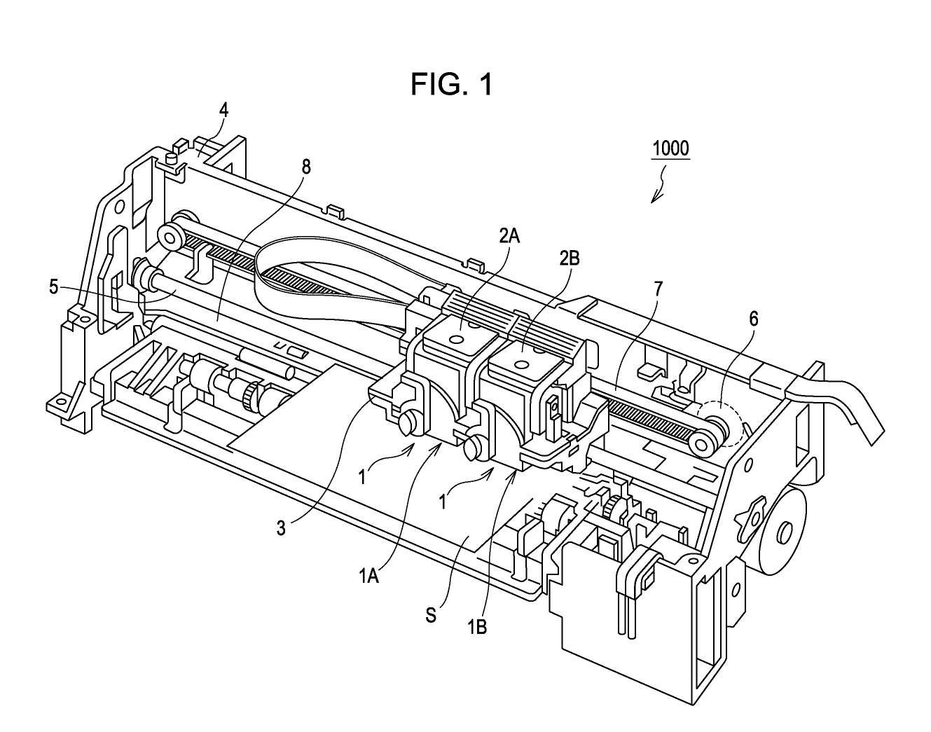

FIG. 1 is a schematic view illustrating an example of an ink jet recording apparatus 1000 as a liquid ejecting apparatus in the embodiment. The ink jet recording apparatus 1000 is an apparatus which ejects ink as liquid onto a recording sheet S as a recording medium so as to perform recording.

In FIG. 1, the ink jet recording apparatus 1000 includes recording head units 1A, 1B each of which has an ink jet recording head 1 as a liquid ejecting head. Cartridges 2A, 2B constituting ink supply units are detachably provided on the recording head units 1A, 1B, respectively.

The ink jet recording heads 1 are provided on the recording head units 1A, 1B at positions opposed to the recording sheet S although not shown in FIG. 1.

A carriage 3 on which the recording head units 1A, 1B are mounted is provided on a carriage shaft 5 so as to be movable in the axial direction thereof. The carriage axis 5 is attached to an apparatus main body 4. For example, the recording head unit 1A discharges black ink composition and the recording head unit 1B discharges color ink composition.

When a driving force of a driving motor 6 is transmitted to the carriage 3 through a plurality of gears (not shown) and a timing belt 7, the carriage 3 on which the recording head units 1A, 1B are mounted moves along the carriage shaft 5.

On the other hand, a platen 8 is provided along the carriage 3 on the apparatus main body 4. The platen 8 can rotate with a driving force of a sheet feeding motor (not shown). The recording sheet S as a recording medium such as a paper which is fed by a sheet feeding roller and the like is transported while being wound around the platen 8.

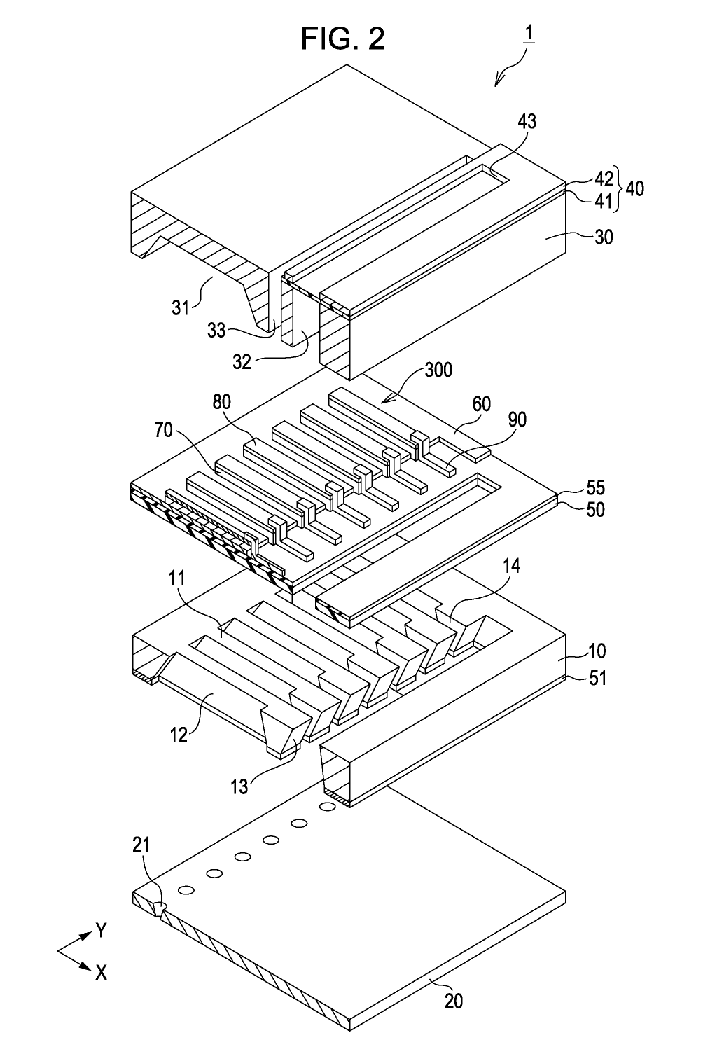

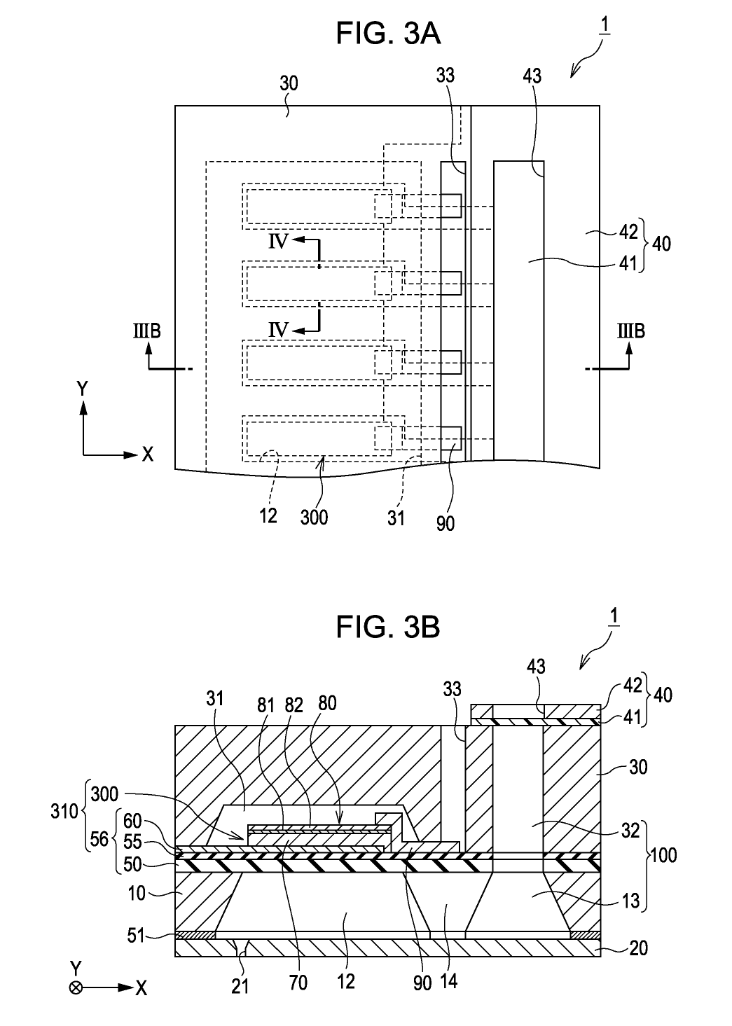

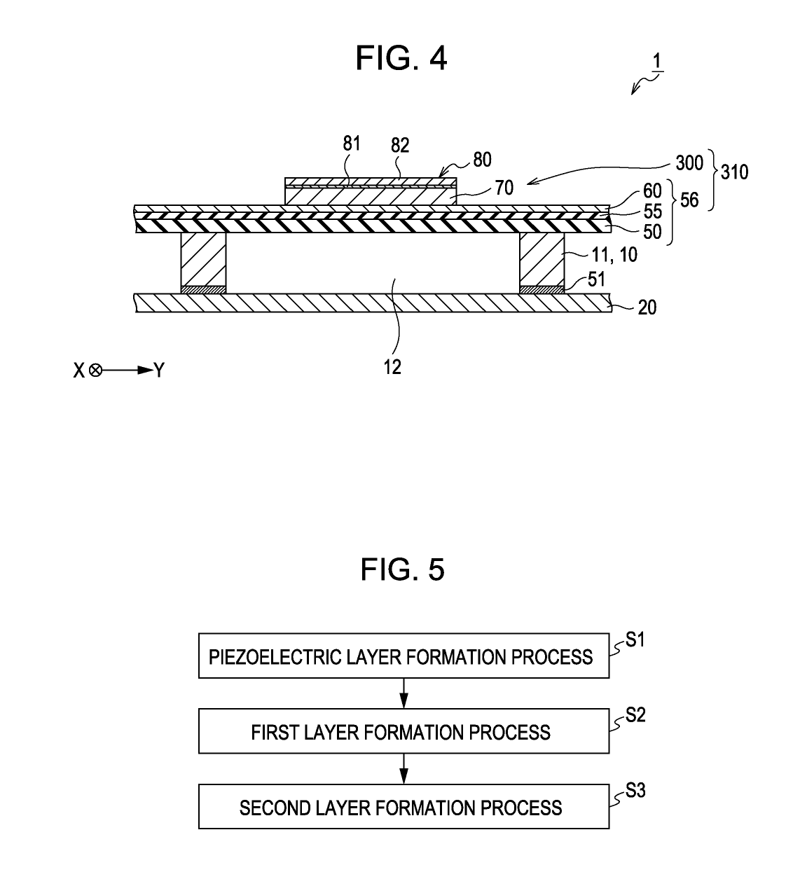

Hereinafter, each ink jet recording head 1 is described in detail with reference to FIG. 2, FIGS. 3A and 3B, and FIG. 4.

FIG. 2 is an exploded perspective view illustrating a schematic configuration of the ink jet recording head 1. FIG. 3A is a fragmentary plan view illustrating the ink jet recording head 1 and FIG. 3B is a schematic cross-sectional view cut along a line IIIB-IIIB in FIG. 3A. FIG. 4 is a schematic fragmentary cross-sectional view cut along a line IV-IV in FIG. 3A. In FIG. 2, FIGS. 3A and 3B, and FIG. 4, some portion is magnified or a dimension ratio is changed for ease of understanding.

In FIG. 2, FIGS. 3A and 3B, and FIG. 4, the ink jet recording head 1 includes a flow path formation substrate 10, a nozzle plate 20, and a protection substrate 30.

The flow path formation substrate 10 is made of a silicon single crystal substrate having a plane orientation of (110), for example. Further, an elastic film 50 having a thickness of 0.50 μm to 2.00 μm is formed on one surface of the flow path formation substrate 10. The elastic film 50 is made of silicon oxide which has been previously formed by thermal oxidation.

The silicon single crystal substrate is anisotropically etched from a surface side opposite to the surface on which the elastic film 50 is formed. With the etching, a plurality of pressure generation chambers 12 are arranged in parallel on the flow path formation substrate 10. The plurality of pressure generation chambers 12 are divided by a plurality of separation walls 11. At the time of the anisotropic etching, the elastic film 50 functions as an etching stopper.

Further, communication portions 13 are formed at outer sides of one end portions of the pressure generation chambers 12 in a direction (which is an X-axis direction as a longitudinal direction) perpendicular to an arrangement direction (which is a Y-axis direction as a width direction) of the pressure generation chambers 12. The communication portions 13 are communicated with a reservoir portion 32 of the protection substrate 30, which will be described later. Further, each communication portion 13 is communicated with each pressure generation chamber 12 at one end portion of the pressure generation chamber 12 in the longitudinal direction through each ink supply path 14.

A mask film 51 used when the pressure generation chambers 12 are formed is provided on a surface of the flow path formation substrate 10 opposite to the surface on which the elastic film 50 is formed. The nozzle plate 20 is fixedly adhered onto the mask film 51 via an adhesive, a thermal welding film or the like. Nozzle openings 21 are provided on the nozzle plate 20 in a perforated manner. The nozzle openings 21 are communicated with portions near end portions of the pressure generation chambers 12 at the side opposite to the ink supply paths 14.

On the other hand, an insulation film 55 having a thickness of approximately 0.40 μm, for example, is formed on the elastic film 50 at the opposite side to the flow path formation substrate 10. Further, a lower electrode 60 having a thickness of approximately 0.20 μm, piezoelectric layers 70 having an average thickness of approximately 0.80 μm and upper electrodes 80 having a thickness of approximately 0.05 μm are laminated and formed on the insulation film 55 so as to constitute piezoelectric elements 300.

It is to be noted that each piezoelectric element 300 is a member including the lower electrode 60, the piezoelectric layer 70 and the upper electrode 80. In general, the piezoelectric element 300 is configured such that one of the electrodes included in the piezoelectric element 300 is set as a common electrode and the other thereof and the piezoelectric layer 70 undergo patterning for each pressure generation chamber 12. Then, a portion which is constituted by any one of the electrodes and the piezoelectric layer 70 which undergo patterning is referred to as a piezoelectric active portion. A piezoelectric strain is caused on the piezoelectric active portion when a voltage is applied to both the electrodes. In either case, the piezoelectric active portion is formed for each pressure generation chamber 12.

In the embodiment, the elastic film 50, the insulation film 55 and the lower electrode 60 serve as a vibration plate 56 which is deformed by driving the piezoelectric elements 300.

Further, a member which includes the piezoelectric element 300 and the vibration plate 56 including portions which are deformed by driving the piezoelectric element 300 together are referred to as an actuator apparatus 310 in the embodiment. The vibration plate may be constituted by only the lower electrode 60. In this case, the piezoelectric element 300 corresponds to an actuator apparatus.

Each of the elastic film 50 and the insulation film 55 constituting the vibration plate 56 may be a layer of at least one type selected from zirconium oxide and aluminum oxide in addition to silicon oxide, for example. Alternatively, each of the elastic film 50 and the insulation film 55 may be a laminated layer formed by laminating these layers.

The pressure generation chambers 12 are formed at least after the piezoelectric layers 70 are formed. At least after the piezoelectric layers 70 are formed, the flow path formation substrate 10 is etched via the mask film 51 so as to form the pressure generation chambers 12. With the method, the piezoelectric layers 70 are deflected in a convex form in the direction that volumes of the pressure generation chambers 12 are increased with the stress of the piezoelectric layers 70, and the like.

The vibration plate 56 has a function of vibrating if the piezoelectric elements 300 are driven. The vibration plate 56 is deformed with operations of the piezoelectric elements 300 so as to change the volumes of the pressure generation chambers 12. If the volumes of pressure generation chamber 12 filled with ink are made smaller, pressures in the pressure generation chambers 12 are increased. Therefore, ink droplets are ejected through the nozzle openings 21 in the nozzle plate 20.

A material of the lower electrode 60 is not particularly limited as long as the material has conductivity. For example, various types of metals such as nickel, iridium, or platinum, conductive oxides thereof (for example, iridium oxide), strontium-ruthenium composite oxide, lanthanum-nickel composite oxide, or the like can be used.

The lower electrode 60 forms a pair with each of the upper electrodes 80 and serves as one of electrodes sandwiching each piezoelectric layer 70. The lower electrode 60 can serve as a common electrode which is common to the plurality of piezoelectric elements 300. The lower electrode 60 is electrically connected to an external circuit (not shown).

As a material of each piezoelectric layer 70, perovskite oxide expressed by a general formula ABO₃ can be preferably used. To be more specific, it is preferable that the piezoelectric layer 70 be made of lead zirconate titanate (Pb(Zr,Ti)O₃) (hereinafter, abbreviated to as “PZT”). However, the piezoelectric layer 70 may contain lead zirconate titanate niobate (Pb(Zr,Ti,Nb)O₃) (hereinafter, abbreviated to as “PZTN (registered trademark)” in some case), barium titanate (BaTiO₃), potassium sodium niobate ((K,Na)NbO₃) or the like.

If electric fields are applied to the piezoelectric layers 70 by the lower electrode 60 and the upper electrodes 80, the piezoelectric layers 70 are deformed in an expanding or contracting manner. Therefore, ink can be mechanically output.

As shown in FIG. 3B and FIG. 4, the upper electrode 80 is formed on the piezoelectric layer 70 and includes a first layer 81 and a second layer 82. The upper electrode 80 may be made of Ir (iridium) or may mainly include Ir.

Hereinafter, a method of manufacturing the actuator apparatus 310 is described in detail.

FIG. 5 is a flowchart illustrating a part of the method of manufacturing the actuator apparatus 310.

The method of manufacturing the actuator apparatus 310 has a step 1 (S1), a step 2 (S2) and a step 3 (S3). The step 1 (S1) corresponds to a piezoelectric layer formation process. The step 2 (S2) corresponds to a first layer formation process and the step 3 (S3) corresponds to a second layer formation process. The first layer formation process and the second layer formation process are included in a process of forming the upper electrode 80.

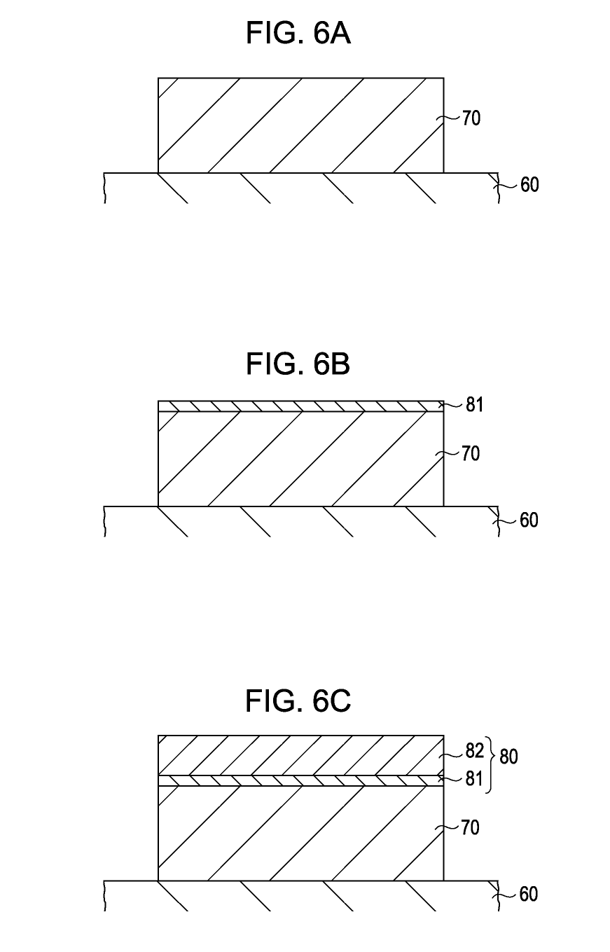

Further, FIGS. 6A through 6C are schematic fragmentary cross-sectional views mainly illustrating a method of manufacturing the upper electrode 80 in the piezoelectric element formation process of the actuator apparatus 310. Each of the schematic fragmentary cross-sectional views in FIGS. 6A through 6C corresponds to a cross-section cut along a line IV-IV in FIG. 3A.

FIG. 6A illustrates the piezoelectric layer formation process (S1), FIG. 6B illustrates the first layer formation process (S2) and FIG. 6C illustrates the second layer formation process (S3).

In FIG. 6A, in the piezoelectric layer formation process (S1), the piezoelectric layer 70 is formed on the lower electrode 60 which has been formed on the flow path formation substrate 10.

In FIGS. 3A and 3B and FIG. 4, the elastic film 50 and the insulation film 55 are formed on the flow path formation substrate 10. The lower electrode 60 is formed on the insulation film 55. In the embodiment, the lower electrode 60, the elastic film 50 and the insulation film 55 constitute the vibration plate 56.

The elastic film 50 and the insulation film 55 as a part of the vibration plate 56 can be formed by a sputtering method, a vacuum deposition method, a CVD method or the like.

The lower electrode 60 is formed by the lower electrode formation process. The lower electrode 60 can be formed as follows. That is, a conductive layer is formed on an entire surface of the elastic film 50 and the insulation film 55 by the sputtering method, the vacuum deposition method, the CVD method or the like, and then, the layer is subjected to patterning with photolithography or the like. Alternatively, the lower electrode 60 may be formed by a method in which patterning is not required, such as a printing method. A thickness of the lower electrode 60 can be set to 0.10 μm to 0.30 μm, for example. Further, the lower electrode 60 may be a single layer made of the above-described material or a laminated structure in which a plurality of materials are laminated on one another.

The piezoelectric layer 70 can be formed by a sol-gel method, the CVD method, or the like. In the sol-gel method, a series of operations including material solution coating, preheating, and crystallization annealing are repeated a plurality of times so as to make the piezoelectric layer 70 have a predetermined thickness.

For example, the piezoelectric layer 70 may be formed by a spin coat method, a printing method or the like using a sol-gel solution containing Pb, Zr, and Ti, for example.

A thickness of the piezoelectric layer 70 can be set to 0.50 μm to 1.50 μm.

In FIG. 6B, in the first layer formation process (S2), the first layer 81 of the upper electrode 80 containing Ir is formed on the piezoelectric layer 70 in a state where the piezoelectric layer 70 is at a temperature of equal to or lower than 250° C. As the temperature of equal to or lower than 250° C., the piezoelectric layer 70 may be formed at a room temperature, for example.

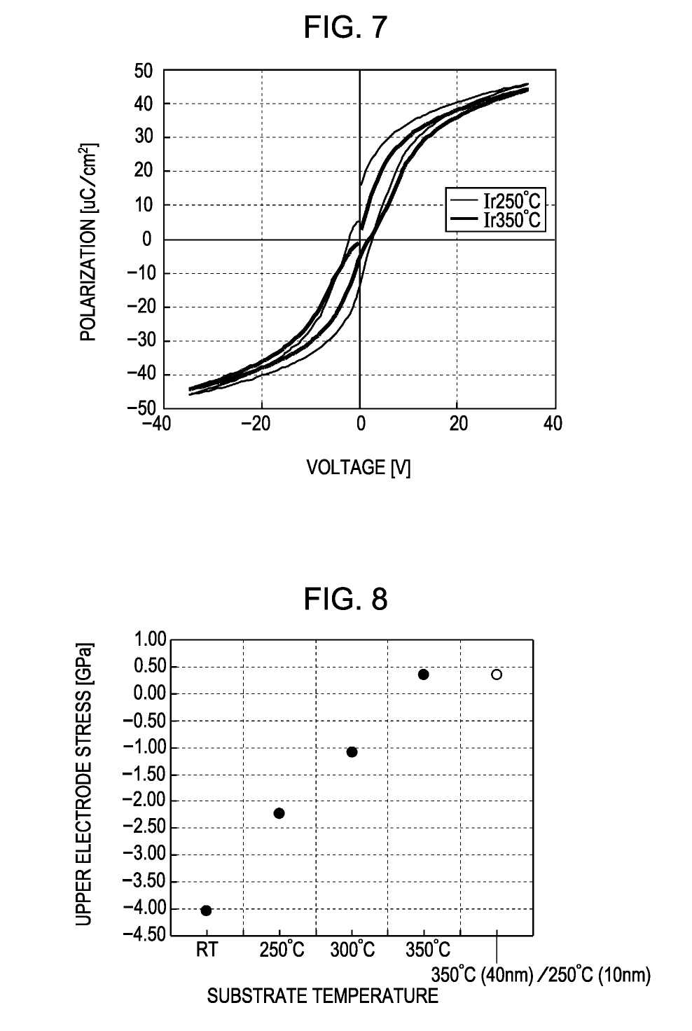

FIG. 7 is a graph expressing changes in conditions of piezoelectric characteristics by differences in a substrate temperature at which a layer is formed (formation temperature) as a hysteresis characteristic. In FIG. 7, a horizontal axis indicates a voltage and a vertical axis indicates a polarization. A case where the substrate temperature is 250° C. is compared with a case where the substrate temperature is 350° C. With the comparison, it is considered that residual polarization is decreased so as to damage the crystal of PZT due to oxygen defect in the case of 350° C.

FIG. 8 is a graph illustrating a relationship between a substrate temperature and a film stress when the piezoelectric layer 70 is set as a substrate of the first layer 81. A thickness of the film is 50 nm. A horizontal axis indicates a substrate temperature and a vertical axis indicates a stress. In FIG. 8, a stress with a negative sign expresses a compression stress.

The film stress becomes smaller as the substrate temperature becomes higher. FIG. 8 indicates that the stress changes from the compression stress to a tensile stress between 300° C. and 350° C. Data indicated by a black circle indicates a stress in a single layer. On the other hand, data indicated by a white circle indicates a stress of the upper electrode 80 when the first layer 81 of 10 nm is formed and the second layer 82 of 40 nm is formed.

In the first layer formation process (S2), the first layer 81 is formed at a substrate temperature of equal to or lower than 250° C. while the piezoelectric layer 70 is set as the substrate. Accordingly, a stress generated on the first layer 81 is a compression stress. The first layer 81 can be formed by using the sputtering method, the vacuum deposition method, or the like. The thickness of the first layer 81 can be set to 10 nm, for example.

In FIG. 6C, in the second layer formation process (S3), the second layer 82 having a tensile stress is formed on the first layer 81 having a compression stress so as to eliminate deflection of the piezoelectric element 300. The second layer 82 having a tensile stress is formed at a substrate temperature of equal to or higher than 350° C. while the piezoelectric layer 70 and the first layer 81 are set as substrates. In order to eliminate the deflection of the piezoelectric element 300, the second layer 82 is formed while adjusting the substrate temperature and the thickness thereof.

The thickness of the second layer 82 can be set to 40 nm, for example.

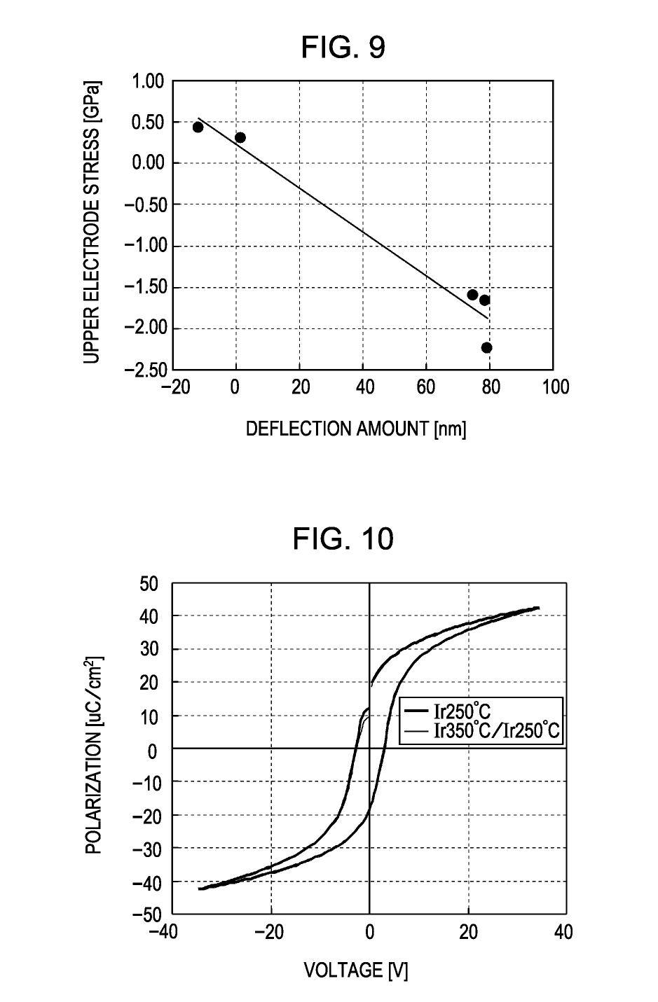

FIG. 9 is a graph illustrating a relationship between a stress of the upper electrode 80 and a deflection amount. A horizontal axis indicates the deflection amount and a vertical axis indicates the stress. In FIG. 9, a stress with a negative sign expresses a compression stress.

In FIG. 9, when the stress of the upper electrode 80 is 0, the deflection amount is substantially zero. However, when the stress of the upper electrode 80 is 0, deflection is slightly present on the piezoelectric element 300 due to the effect of the stresses by the lower electrode 60 and the piezoelectric layer 70.

The actuator apparatus 310 is obtained by processes including the above-described piezoelectric element formation process.

In FIG. 2 and FIGS. 3A and 3B, lead electrodes 90 which are electrically connected to the upper electrodes 80 are provided on the piezoelectric elements 300. For example, the lead electrodes 90 can be provided so as to be electrically connected to the upper electrodes 80 in an extending manner. The lead electrodes 90 are electrically connected to circuit elements or the like. When the piezoelectric elements 300 have protection films, a configuration in which through-holes are formed on the protection films so as to connect the upper electrodes 80 and the lead electrodes 90 may be employed.

The protection substrate 30 having a piezoelectric element holder 31 is bonded to the flow path formation substrate 10 at the side of the piezoelectric elements 300 with an adhesive. The piezoelectric element holder 31 can ensure a space on a region opposed to the piezoelectric elements 300 to an extent that the motions of the piezoelectric elements 300 are not hindered. The piezoelectric elements 300 are formed within the piezoelectric element holder 31. Therefore, the piezoelectric elements 300 are protected so as not to be influenced by outside environment.

It is to be noted that a space in the piezoelectric element holder 31 may be or may not be sealed.

Further, the reservoir portion 32 is provided on the protection substrate 30. The reservoir portion 32 is communicated with the communication portions 13 on the flow path formation substrate 10 so as to constitute a reservoir 100 as a common ink chamber which is common to each of the pressure generation chambers 12. In addition, a through-hole 33 is provided on the protection substrate 30 at a region between the piezoelectric element holder 31 and the reservoir portion 32. The through-hole 33 penetrates through the protection substrate 30 in the thickness direction thereof. Portions near the ends of the lead electrodes 90 extended from the piezoelectric elements 300 are exposed in the through-hole 33.

Further, a compliance substrate 40 including a sealing film 41 and a fixing plate 42 is bonded onto the protection substrate 30. Further, the fixing plate 42 is made of a hard material such as a metal. A region which is opposed to the reservoir 100 corresponds to an opening 43 from which the fixing plate 42 is completely removed in the thickness direction thereof. Therefore, one side surface of the reservoir 100 is sealed only by the sealing film 41 having flexibility.

In the ink jet recording head 1 having the above configuration, ink is taken from an external ink supply unit (not shown) so as to fill the inner portion from the reservoir 100 to the nozzle opening 21 with the ink. Thereafter, a driving voltage is applied to between the lower electrode 60 and each upper electrode 80 corresponding to each pressure generation chamber 12 in accordance with a driving signal transmitted from a driving IC (not shown). Then, the elastic film 50, the insulation film 55, the lower electrode 60 and the piezoelectric layers 70 are deflected and deformed. Therefore, pressures in the pressure generation chambers 12 are increased so that ink droplets are discharged through the nozzle openings 21.

The piezoelectric layers 70, the upper electrodes 80, the lead electrodes 90 and the like are formed on a wafer. Finally, the piezoelectric layers 70, the upper electrodes 80, the lead electrodes 90 and the like are divided from the wafer so that the plurality of ink jet recording heads 1, piezoelectric elements 300, and actuator apparatuses 310 can be obtained. Further, the obtained ink jet recording head 1 is incorporated so as to obtain the ink jet recording apparatus 1000.

FIGS. 10, 11 and 12 are graphs illustrating a hysteresis characteristic, a deflection reduction transition, and a displacement reduction rate, respectively, in each of a case where Ir of 50 nm is formed at 250° C. as the upper electrode and a case where the first layer 81 of 10 nm is formed at 250° C. and the second layer 82 of 40 nm is formed at 350° C. as the upper electrode 80.

In FIG. 10, a horizontal axis indicates a voltage and a vertical axis indicates a polarization. Difference in the hysteresis characteristics is not substantially observed between the case where Ir of 50 nm is formed at 250° C. as the upper electrode and the case where the first layer 81 of 10 nm is formed at 250° C. and the second layer 82 of 40 nm is formed at 350° C. as the upper electrode 80. Accordingly, in this case, it is considered that the crystal of PZT is not damaged due to oxygen defect unlike FIG. 7.

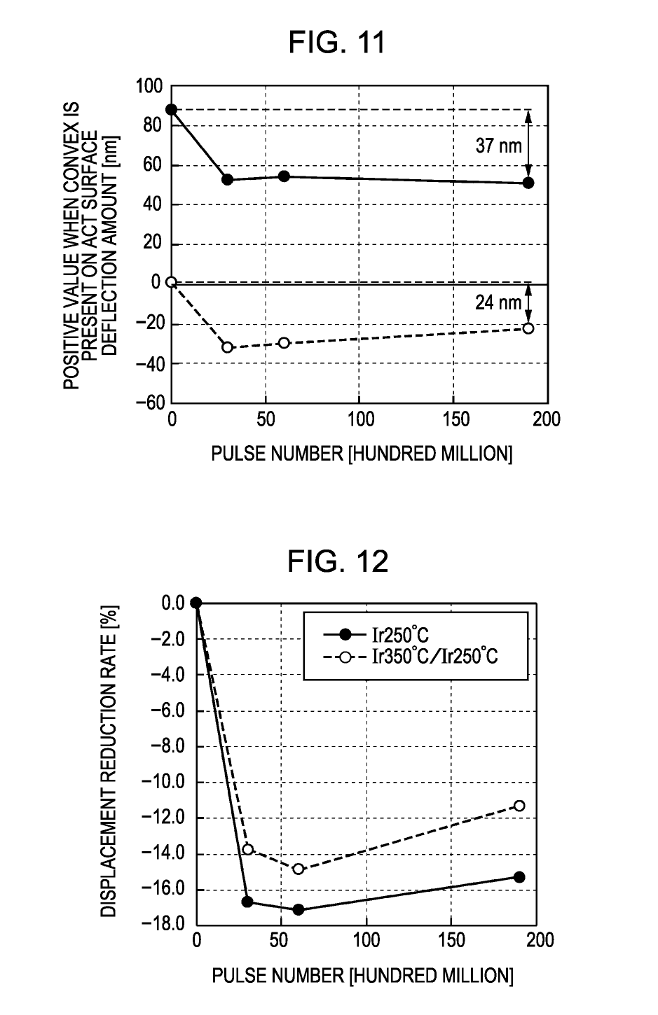

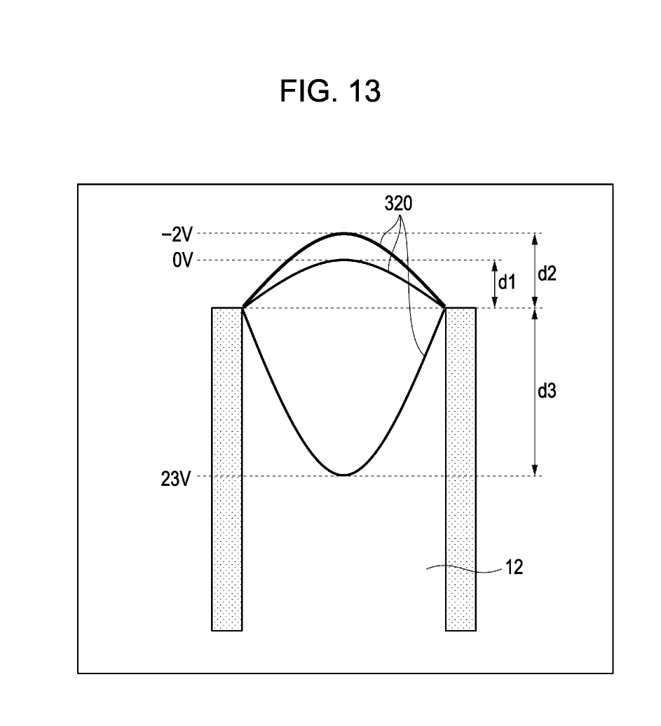

In FIG. 11, a horizontal axis indicates the number of pulses to be applied and a vertical axis indicates a deflection amount. Further, in FIG. 11, a point indicating the number of pulses and a deflection amount in the case where Ir of 50 nm is formed at 250° C. as the upper electrode is indicated by a black circle and a point indicating the number of pulses and a deflection amount in the case where the first layer 81 of 10 nm is formed at 250° C. and the second layer 82 of 40 nm is formed at 350° C. as the upper electrode 80 is indicated by a white circle.

Reduction from an initial deflection amount was 37 nm at the nineteen billion pulses in the case where Ir of 50 nm is formed at 250° C. as the upper electrode. On the other hand, the reduction from an initial deflection amount was 24 nm at the nineteen billion pulses in the case where the first layer 81 of 10 nm is formed at 250° C. and the second layer 82 of 40 nm is formed at 350° C. as the upper electrode 80.

In FIG. 12, a horizontal axis indicates the number of pulses to be applied and a vertical axis indicates a displacement reduction rate. Further, in FIG. 12, a point indicating the number of pulses and a displacement reduction rate in the case where Ir of 50 nm is formed at 250° C. as the upper electrode is indicated by a black circle and a point indicating the number of pulses and a deflection amount in the case where the first layer 81 of 10 nm is formed at 250° C. and the second layer 82 of 40 nm is formed at 350° C. as the upper electrode 80 is indicated by a white circle. The displacement reduction rate is relatively low in the case where the first layer 81 of 10 nm is formed at 250° C. and the second layer 82 of 40 nm is formed at 350° C. as the upper electrode 80 in comparison with the case where Ir of 50 nm is formed at 250° C. as the upper electrode.

A half-value width in the case where the first layer 81 of 10 nm is formed at 250° C. and the second layer 82 of 40 nm is formed at 350° C. as the upper electrode 80 is smaller than that in the case where Ir of 50 nm is formed at 250° C. as the upper electrode. Therefore, crystallinity of the upper electrode 80 containing Ir is improved in the case where the first layer 81 of 10 nm is formed at 250° C. and the second layer 82 of 40 nm is formed at 350° C. as the upper electrode 80.

A sheet resistance value of the upper electrode 80 containing Ir is small in the case where the first layer 81 of 10 nm is formed at 250° C. and the second layer 82 of 40 nm is formed at 350° C. as the upper electrode 80 in comparison with that in the case where Ir of 50 nm is formed at 250° C. as the upper electrode.

According to the above-described embodiment, the following effects can be obtained.

(1) A temperature of the piezoelectric layer 70 containing PZT when the first layer 81 of the upper electrode 80 is formed is equal to or lower than 250° C. Therefore, oxygen defect of the PZT can be suppressed from being generated. Further, if the first layer 81 containing Ir is formed on the piezoelectric layer 70 in a state where the piezoelectric layer 70 as a substrate is at the temperature of equal to or lower than 250° C., a compression stress is generated on the first layer 81. Then, the second layer 82 having a tensile stress is formed on the first layer 81 on which the compression stress is generated. This makes it possible to eliminate deflection on the entire piezoelectric element 300. Accordingly, since an initial deflection is small, reduction in the deflection amount of the piezoelectric element 300 which has been deflected in a convex form can be suppressed. Note that the deflection of the piezoelectric element 300 occurs because the piezoelectric element 300 has been repeatedly displaced. Therefore, a method of manufacturing the actuator apparatus 310 in which reduction in a displacement amount can be suppressed can be obtained.

Further, the deflection does not change from the convex form to a concave form. Therefore, an excessive stress is not applied to the piezoelectric element 300. Accordingly, a method of manufacturing the actuator apparatus 310 in which cracks can be suppressed from being generated and film detachment between the lower electrode 60 and the upper electrode 80 can be suppressed can be obtained.

(2) If the temperature at which the second layer 82 containing Ir is formed is equal to or higher than 350° C., the second layer 82 having a tensile stress can be obtained. By forming the second layer 82, deflection of the first layer 81 on which the compression stress is generated can be reduced. Accordingly, a method of manufacturing the actuator apparatus 310 having the above-described effect can be obtained.

(3) Since the thickness of the second layer 82 is larger than that of the first layer 81, the tensile stress of the second layer 82 is dominant. If the thickness of the first layer 81 is set to 10 nm and that of the second layer 82 is set to 40 nm in the upper electrode 80 containing Ir, the deflection on the entire piezoelectric element 300 can be eliminated. Accordingly, a method of manufacturing the actuator apparatus 310 having the above-described effect can be obtained.

(4) A method of manufacturing the ink jet recording head 1 and a method of manufacturing the ink jet recording apparatus 1000, which have the above-described effect, can be obtained.

(5) Since an initial deflection of the piezoelectric element 300 is small, reduction in the deflection amount of the piezoelectric element 300 which has been deflected in a convex form can be suppressed. Note that the deflection of the piezoelectric element 300 occurs because the piezoelectric element 300 has been repeatedly displaced. Therefore, a method of manufacturing the actuator apparatus 310 in which reduction in the displacement amount can be suppressed can be obtained.

(6) When the thickness of the first layer 81 is 10 nm and that of the second layer 82 is 40 nm, an actuator apparatus 310 having the above-described effect can be obtained.

Various modifications can be made in addition to the above embodiment.

For example, the substrate of the actuator apparatus 310 is not limited to the flow path formation substrate 10. For example, a semiconductor substrate, a resin substrate or the like can be arbitrarily used depending on applications.

Further, a plate in which metal layers such as a stainless steel are laminated may be employed as the vibration plate 56, for example.

Further, in the above embodiment, the ink jet recording head 1 has been described as an example of the liquid ejecting head. However, the invention can be widely applied to the liquid ejecting heads in general and can be also applied to liquid ejecting heads which eject liquid other than ink, of course. As another liquid ejecting heads, for example, various types of recording heads which are used in an image recording apparatus such as a printer, a color material ejecting head which is used for manufacturing a color filter such as a liquid crystal display, an electrode material ejecting head which is used for forming an electrode such as an organic EL display or a field emission display (FED), a bioorganic compound ejecting head which is used for manufacturing a bio chip, and the like can be exemplified.

What is claimed is:

1. A method of manufacturing an actuator apparatus which includes a piezoelectric element formed by sandwiching a piezoelectric layer containing PZT between a lower electrode and an upper electrode containing Ir, the method comprising:
forming a first layer of the upper electrode on the piezoelectric layer in a state where the piezoelectric layer is at a temperature of equal to or lower than 250° C.; and
forming a second layer having a tensile stress on the first layer.

2. The method of manufacturing the actuator apparatus according to claim 1,
wherein a temperature at which the second layer is formed is equal to or higher than 350° C.

3. The method of manufacturing the actuator apparatus according to claim 1,
wherein a thickness of the first layer is 10 nm and a thickness of the second layer is 40 nm.

4. A method of manufacturing a liquid ejecting head having an actuator apparatus that includes a piezoelectric element formed by sandwiching a piezoelectric layer containing PZT between a lower electrode and an upper electrode containing Ir, the method comprising:
forming a first layer of the upper electrode on the piezoelectric layer in a state where the piezoelectric layer is at a temperature of equal to or lower than 250° C.; and
forming a second layer having a tensile stress on the first layer.

5. The method of manufacturing the liquid ejecting head according to claim 4,
wherein a temperature at which the second layer is formed is equal to or higher than 350° C.

6. The method of manufacturing the liquid ejecting head according to claim 4,
wherein a thickness of the first layer is 10 nm and a thickness of the second layer is 40 nm.

7. A method of manufacturing a liquid ejecting apparatus having a liquid ejecting head, the liquid ejecting head having an actuator apparatus that includes a piezoelectric element formed by sandwiching a piezoelectric layer containing PZT between a lower electrode and an upper electrode containing Ir, the method comprising:
forming a first layer of the upper electrode on the piezoelectric layer in a state where the piezoelectric layer is at a temperature of equal to or lower than 250° C.; and
forming a second layer having a tensile stress on the first layer.

8. The method of manufacturing the liquid ejecting apparatus according to claim 7,
wherein a temperature at which the second layer is formed is equal to or higher than 350° C.

9. The method of manufacturing the liquid ejecting apparatus according to claim 7,
wherein a thickness of the first layer is 10 nm and a thickness of the second layer is 40 nm.

10. An actuator apparatus comprising a piezoelectric element formed by sandwiching a piezoelectric layer containing PZT between a lower electrode and an upper electrode containing Ir,
wherein the upper electrode includes a first layer and a second layer, and
the piezoelectric element is not deflected.

11. The actuator apparatus according to claim 10,
wherein a thickness of the first layer is 10 nm and a thickness of the second layer is 40 nm.
